(19) United States
(12) Patent Application Publication
(10) Pub. No.: US 2012/0176139 A1
(43) Pub. Date: Jul. 12, 2012

(54) SYSTEM AND METHOD FOR SENSING MULTIPLE USER INPUT SWITCH DEVICES

(75) Inventors: Swee Lin Thor, Penang (MY); Mark Ging Yeon Wong, Sarawak (MY); Wai Lian Teo, Penang (MY)

(73) Assignee: AVAGO TECHNOLOGIES ECBU IP (SINGAPORE) PTE. LTD., Singapore (SG)

(21) Appl. No.: 13/005,493

(22) Filed: Jan. 12, 2011

(51) Int. Cl. G01R 31/327

(52) U.S. Cl. 324/415

(57) ABSTRACT

A system and method for sensing multiple user input switch devices uses a generated sense current that corresponds to an electrical current through a node to which the user input switch devices are connected to sense current states of the user input switch devices. The sense current is used to produce multiple output signals that indicate the current states of the user input switch devices.

### BACKGROUND OF THE INVENTION

User input switch devices, such as buttons, are used in various electronics products for users to input commands. As an example, left and right buttons are commonly found in a computer mouse for users to selectively press to activate a right mouse click or a left mouse click, which are essential when using the optical mouse to perform various operations in a computer operating environment.

A common technique to sense the activation of a user input switch device, which is typically mounted on a printed circuit board, is to use a sense circuit with a receiver and a weak pull-up transistor in an integrated circuit (IC). The printed circuit board is connected to the IC via a pin of the IC, which is commonly known as an IC package pin. The input of the receiver, the drain of the weak pull-up transistor and one terminal of the user input switch device are connected to the pin of the integrated circuit board. The other terminal of the user input switch device is connected to ground. The weak pull-up transistor is always enabled. When the user input switch device is open, i.e., not activated, the voltage at the pin is same as the supply power voltage due to the weak pull-up transistor. Hence, the receiver will output a high signal. When the user input device is closed, i.e., activated, the pin will be shorted to ground. Since the voltage at the pin is zero, the receiver will output a low signal. The output signal of the receiver is used to determine whether the user input switch device has been activated or not.

A concern with the above technique to sense a user input switch device is that, if there are multiple user input switch devices, each user input switch device will need an input pin on an IC that includes a sense circuit for the user input switch devices. This will increase pin count on the IC and increase the cost of the IC and the final product.

Therefore, there is a need for a system and method for sensing multiple user input switch devices with reduced pin count on an integrated circuit with a sense circuit.

### SUMMARY OF THE INVENTION

A system and method for sensing multiple user input switch devices uses a generated sense current that corresponds to an electrical current through a node to which the user input switch devices are connected to sense current states of the user input switch devices. The sense current is used to produce multiple output signals that indicate the current states of the user input switch devices.

In an embodiment, a system comprises a plurality of user input switch devices and a sense circuit. Each of the user input switch devices is configured to be switched between two states. Each of the user input switch devices is connected to a node and connected in parallel to each other. The sense circuit is electrically connected to the user input switch devices through the node. The sense circuit is configured to generate a sense current that corresponds to an electrical current through the node when at least one of the user input switch device is switched to one of the two states. The sense circuit is configured to produce multiple output signals based on the sense current, wherein the multiple output signals indicate current states of the user input switch devices.

In another embodiment, a system comprises a plurality of user input switch devices and a sense circuit. Each of the user input switch devices is configured to be switched between two states. Each of the user input switch devices is connected in parallel to each other. Each of the user input switch devices is connected in series with one of a plurality of resistors between a node and a low voltage rail. The sense circuit is electrically connected to the user input switch devices through the node. The sense circuit is configured to generate a sense current that corresponds to an electrical current through the node when at least one of the user input switch device is switched to one of the two states. The sense circuit is configured to produce multiple output signals based on the sense current, wherein the multiple output signals indicate current states of the user input switch devices.

In an embodiment, a method for sensing multiple user input switch devices comprises providing a supply power to the user input switch devices through a node to which each of the user input switch devices is connected, each of the user input switch devices being configured to be switched between two states, generating a sense current that corresponds to an electrical current through the node when at least one of the user input switch device is switched to one of the two states at a sense circuit connected to the user input switch devices through the node, and producing multiple output signals based on the sense current at the sense circuit, wherein the multiple output signals indicate current states of the user input switch devices.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a block diagram of a system for sensing multiple user input switch devices in accordance with an embodiment of the invention.

FIG. 2 is a block diagram of components of a sense circuit of the system of FIG. 1 in accordance with an embodiment of the invention.

FIG. 3 is a process flow diagram of a method for sensing multiple user input switch devices in accordance with an embodiment of the invention.

### DETAILED DESCRIPTION

It will be readily understood that the components of the embodiments as generally described herein and illustrated in the appended figures could be arranged and designed in a wide variety of different configurations. Thus, the following detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment. Rather, language referring to the features and advantages is understood to mean that a specific feature, advantage, or characteristic described in connection with an embodiment is included in at least one embodiment. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment. Thus, the phrases “in one embodiment,” “in an embodiment,” and similar language throughout this specification may, but do not necessarily, all refer to the same embodiment.

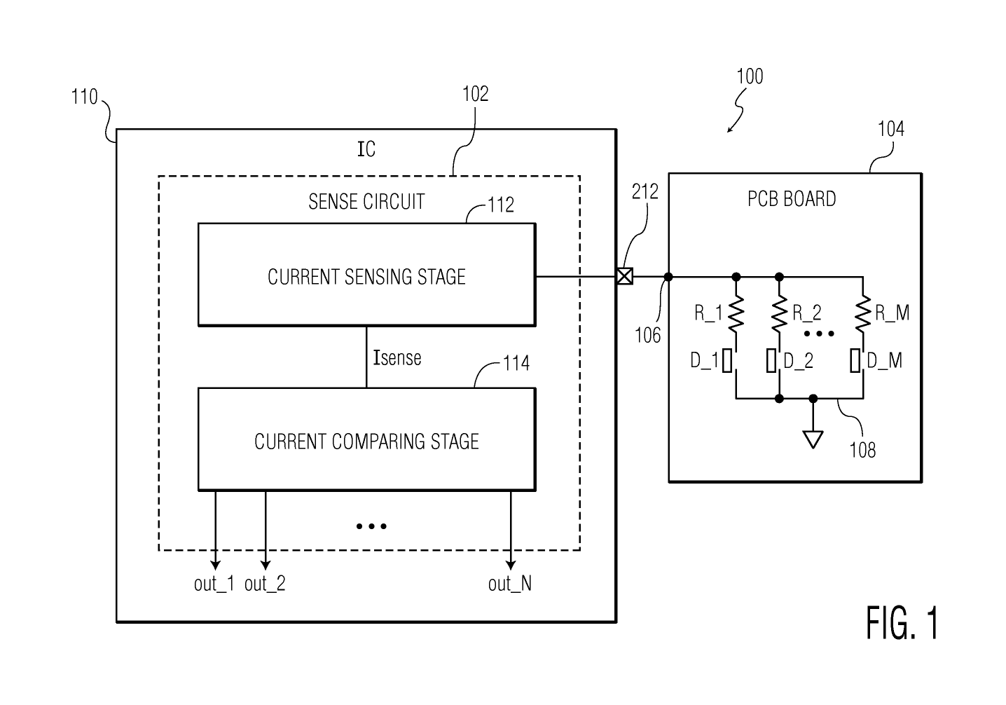

With reference to FIG. 1, a system 100 for sensing multiple user input switch devices in accordance with an embodiment of the invention is shown. As shown in FIG. 1, the system includes multiple user input switch devices D_1, D_2 . . . D_M and a sense circuit 102. The user input switch devices can be any user input devices that can be controlled by users to be switched between two states. Thus, each user input switch device may be configured to be switched between a first state and a second state by a user. In an embodiment, the first state of the user input switch devices may be an activated state and the second state of the user input switch devices may be a deactivated state. Examples of the user input switch devices includes buttons, toggle switches, rocker switches and other types of switches. In an embodiment, the user input switch devices may include left and right buttons that are commonly found in a computer mouse for a user to selectively press to activate a right mouse click or a left mouse click.

As illustrated in FIG. 1, the user input switch devices D_1, D_2 . . . D_M are mounted on a single printed circuit board 104. However, in other embodiments, the user input switch devices may be mounted on more than one printed circuit boards. The printed circuit board includes resistors R_1, R_2 . . . R_M. Each resistor is connected in series with one of the user input switch devices D_1, D_2 . . . D_M between an electrical node 106 and a low voltage rail 108, e.g., electrical ground. The user input switch devices are connected in parallel relative to each other. Thus, the resistors are also connected in parallel relative to each other. Consequently, each series connected pair of resistor and user input switch device provides a current path from the node to the low voltage rail when the user input switch device of that pair is closed, e.g., pressed or activated. The resistors are configured to have different resistance values. In an embodiment, the resistance values of the resistors have the following relationship: R_1=2*R_2=4*R_3=8*R_4 . . . 2^{M-1}*R_M, where R_1, R_2, R_3, R_4 . . . R_M are the resistance values of the resistors R_1, R_2, R_3 and . . . R_M.

The sense circuit 102 operates to sense when one or more of the user input switch devices D_1, D_2 . . . D_M have been switched to the closed state. As described in more detail below, the sense circuit produces output signals that indicate which user input switch devices have been turned on. For example, if the user input switch devices are pressed, the sense circuit will produce output signals that indicate which buttons have been pressed. In the illustrated embodiment, the sense circuit is part of an integrated circuit 110 formed on a semiconductor chip. The sense circuit includes a current sensing stage 112 and a current comparing stage 114. The current sensing stage operates to sense the electrical current through the node 106 and to generate an electrical sense current Isense, which corresponds to the current through the node. The electrical current through the node varies in strength when one or more user input switch devices are closed. Thus, the sense current Isense also varies in strength when one or more user input switch devices are activated. The current comparing stage operates to compare the sense current Isense with reference currents to generate N output signals out_1 . . . out_N, where N equals 2^{M} (M=the total number of user input switch devices). These output signals vary according to the strength of the sense current Isense. Thus, the output signals of the current comparing stage provide information regarding which of the user input switch devices have been closed, e.g., activated.

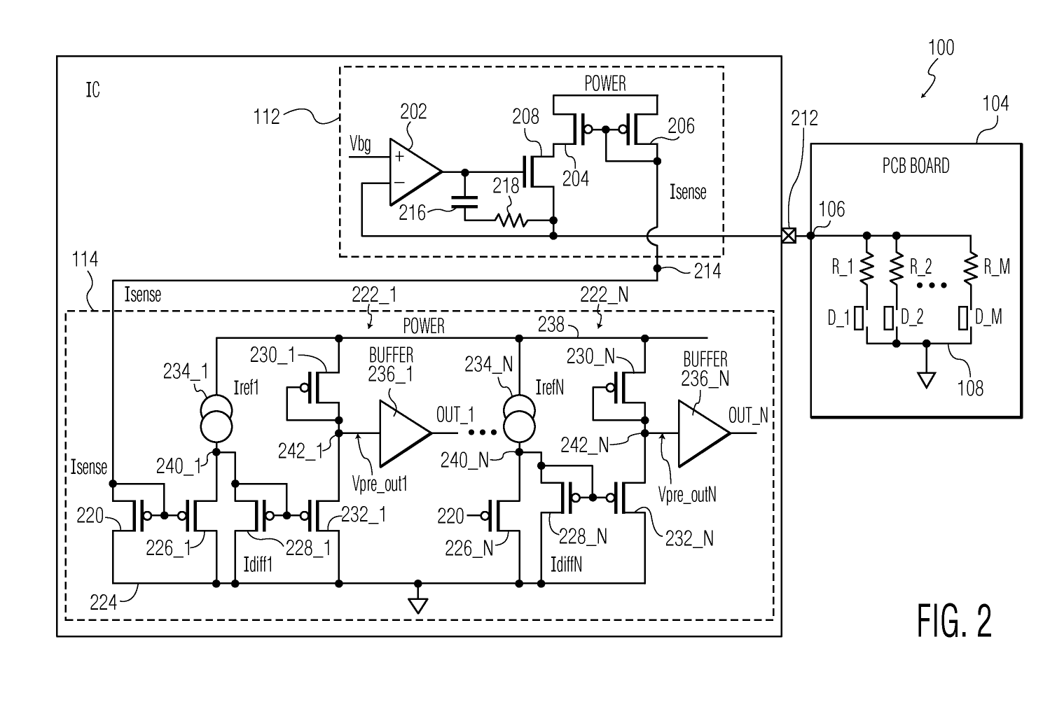

Turning now to FIG. 2, components of the current sensing stage 112 and the current comparing stage 114 of the sense circuit 102 in accordance with an embodiment of the invention are shown. As illustrated in FIG. 2, the current sensing stage includes an operational amplifier 202 and transistors 204, 206 and 208. In the illustrated embodiment, the transistors 204 and 206 are PMOS transistors and the transistor 208 is an NMOS transistor. However, in other embodiments, these transistors can be other types of transistors. The transistors 204 and 208 are connected in series between a power supply rail 210 and an electrical connector 212, which is connected to the node 106 of the printed circuit board 104. In an embodiment, the electrical connector is a pin of the IC 110 that includes the sense circuit, which is commonly referred to as an IC package pin. The transistor 206 is connected in parallel to the transistor 204 between the power supply rail and an output node 214. The control terminals, or gates, of the transistors 204 and 206 are connected to each other and to the output node. Thus, the transistors 204 and 206 form a current mirror so that the current at the output node equals the sense current Isense. The control terminal, or the gate, of the transistor 208 is connected to the output of the operational amplifier. Thus, the output signal of the operational amplifier controls the transistor 208. One of the inputs of the operational amplifier is connected to receive a stable predefined voltage Vbg, e.g., 1.13 Volts in one implementation. The other input of the operational amplifier is connected to the transistor 208 and the electrical connector. Thus, a feedback loop is formed from the transistor 208 to the operational amplifier.

In the illustrated embodiment, the current sensing stage 112 further includes a capacitor 216 and a resistor 218, which are connected in series between the output of the operational amplifier 202 and the electrical connector 212. The series connected capacitor and resistor are used for frequency compensation so that the voltage at the electrical connector will be stable.

In operation, the current sensing stage 112 of the sense circuit 102 generates the sense current Isense when one or more of the user input switch devices D_1, D_2 . . . D_M are closed, e.g., pressed. The strength of the sense current Isense will vary depending on which user input switch devices are closed. As an example, if the user input switch device D_1 is closed, a current path will be formed from the supply voltage rail 210 to the low voltage rail 108 through the transistors 204 and 208, the electrical connector 212, the resistor R_1 and the user input switch device D_1. The current through the transistor 204 is mirrored through the transistor 206 to produce the sense current Isense. The sense current Isense in this example will be defined as:

Isense=Vbg/R_{—}1=ID_{—}1, (Equation 1)

where ID_1 is the current through the user input switch device D_1 and R_1 is the resistance value of the resistor R_1. Since the resistance of the resistor R_1 is much greater than the resistance of the user input switch device D_1, the resistance of the user input switch device D_1 is negligible, and thus, can be ignored in the above equation. When only one of the user input switch devices is closed, the sense current Isense will be defined as:

Isense=Vbg/Ri=IBi, (Equation 2)

where i=1, 2 . . . or M. Equation 2 is a generalized version of Equation 1. However, when more than one of the user input switch devices are closed, the sense current Isense will be the sum of the currents through the closed user input switch devices. Thus, for any number of closed user input switch devices, the sense current Isense will be defined as:

Isense=ΣVbg/Ri=ID_{—}1+ID_{—}2 . . . +ID_{—}M, (Equation 3)

where ID_1 is the current through the user input switch device D_1 and R_1 is the resistance value of the resistor R_1. Since the resistances of the resistors R_1, R_2 . . . R_M are different, the strength of the sense current Isense will be unique for every possible combination of closed and open user input switch devices. That is, for each possible combination of one or more closed user input switch devices, the sense current Isense will be unique. Thus, the sense current Isense indicates which of the user input switch devices have been closed, e.g., pressed.

As shown in FIG. 2, the current comparing stage 114 of the sense circuit 102 includes a transistor 220 and current comparators 222_1 . . . 222_N, where N is equal to 2^{M}−1 in which M is the total number of the user input switch devices. The transistor 220 is connected to the output node 214 of the current sensing stage 112. Thus, the current received at the transistor 220 is the sense current Isense. The transistor 220 is also connected to a low voltage rail 224, e.g., electrical ground. The control terminal, i.e., the gate, of the transistor 220 is connected to the output node. The current through the transistor 220 is the sense current Isense. In the illustrated embodiment, the transistor 220 is an NMOS transistor. However, in other embodiments, the transistor 220 may be a different type of transistor.

Each of the current comparators 222_1 . . . 222_N is configured to compare the sense current Isense to a unique reference current and to generate an output signal based on the difference between the sense current Isense and that reference current. In an embodiment, each of the current comparators is configured to generate either a high signal or a low signal, which represent a logical “0” and a logical “1,” respectively. In the illustrated embodiment, each of the current comparators includes similar components. Thus, only the current comparator 222_1 is described in detail below as an example of the current comparators.

As shown in FIG. 2, the current comparator 222_1 includes transistors 226_1, 228_1, 230_1 and 232_1, a reference current source 234_1 and a buffer 236_1. In the illustrated embodiment, the transistor 230_1 is a PMOS transistor and the transistors 226_1, 228_1, and 232_1 are NMOS transistors. However, in other embodiments, the transistors 226_1, 228_1, and 232_1 can be other types of transistors. The transistor 226_1 is configured to mirror the current through the transistor 220. Thus, the control terminal, i.e., the gate, of the transistor 226_1 is connected to the control terminal of the transistor 220 so that the voltages on the control terminals of the transistors 220 and 226_1 are tied together. In addition, the size of the transistor 226_1 is same as the transistor 220. Thus, the current through the transistor 226_1 will be same as the current Isense. The transistor 226_1 is connected in series with the reference current source 234_1 between a power supply rail 238 and the low voltage rail 224 such that the reference current source is connected to the power supply rail and the transistor 226_1 is connected to the low voltage rail. The reference current source and the transistor 226_1 are connected to each other at a node 240_1. The reference current source is configured is configured to generate a reference current Iref1.

The transistor 228_1 is connected to the node 240_1 and the low voltage rail 224 on a parallel current path from the transistor 226_1. The control terminal, i.e., the gate, of the transistor 228_1 is connected to the node 240_1. The current through the transistor 228_1 is referred to herein as the difference current Idiff, which equals the reference current Iref1 minus the current through the transistor 226_1, i.e., the sense current Isense. Thus, the current Idiff through the transistor 228_1 can be expressed as Iref1−Isense.

The transistor 232_1 is configured to mirror the current through the transistor 228_1. Thus, the current through the transistor 228_1 will also be equal to the difference current Idiff or Iref1−Isense. The control terminal, i.e., the gate, of the transistor 232_1 is connected to the control terminal of the transistor 228_1 so that the voltages on the control terminals of the transistors 228_1 and 232_1 are tied together. In addition, the size of the transistor 232_1 is same as the transistor 228_1. The transistor 232_1 is connected in series with the transistor 230_1 between the power supply rail 238 and the low voltage rail 224. Specifically, the transistor 230_1 is connected to the power supply rail, while the transistor 230_1 is connected to the low voltage rail. The transistors 230_1 and 232_1 are connected to each other at a node 242_1, which is connected to the buffer 236_1.

The transistor 230_1 serves as an active load, and for simplicity, can be viewed as a resistor. The resistance of the transistor 230_1 depends on its size. The voltage Vpre_out1 at the node 242_1 is defined by the current through the transistor 232_1 and the resistance of the transistor 230_1 according to the following equation:

Vpre_out1=Vpower−IdifF*Rₜᵣₐₙₛᵢₛₜₒᵣ, (Equation 4)

where Vpower is the voltage of the power supply on the power supply rail 238, Idiff is the difference current through the transistor 232, and Rₜᵣₐₙₛᵢₛₜₒᵣ is the on/off resistance of the transistor 230_1. The output signal out_1 from the buffer 236_1 is the buffered version of the signal at the node, i.e., the voltage Vpre_out1. In a particular implementation, the buffer includes two series connected inverters that produce the output signal out_1.

When the reference current Iref1 provided by the reference current source 234_1 is greater than the current through the transistor 226_1, i.e., the sense current Isense, there will be some current flow to the transistor 228_1. The current through the transistor 228_1 will be:

Idiff=Iref1−Isense, (Equation 5)

wherein Idiff is the current through the transistor 228_1, Iref1 is the reference current provided by the reference current source 234_1 and Isense is the current through the transistor 226_1. Since the current through the transistor 228_1 is mirrored by the transistor 232_1, the current through the transistor 232_1 will also be equal to Iref1−Isense, which would be greater than zero. If the current through the transistor 228_1 is large, i.e., greater than zero by a threshold, then the voltage Vpre_out1 at the node 242_1 will be low, and thus, the output signal out_1 will also be low.

When the reference current Iref1 provided by the reference current source 234_1 is smaller than the current Isense through the transistor 226_1, all the current from the reference current source will flow through the transistor 226_1. Hence, practically no current will flow through the transistor 228_1, and thus, Idiff=0. Since the current through the transistor 228_1 is mirrored by the transistor 232_1, the current through the transistor 232_1 will also be zero. As noted above, the voltage Vpre_out1 at the node 242_1 is defined as Vpre_out1=Vpower−Idiff*Rₜᵣₐₙₛᵢₛₜₒᵣ. Since the current Idiff through the transistor 232_1 is zero, the voltage Vpre_out1 will be the voltage of the power supply, and thus, will be high. Consequently, the output signal out_1 will also be high.

The other current comparators 222_2 . . . 222_N include the same components found in the current comparator 222_1. However, the reference current sources Iref2 . . . IrefN of the other current comparators are configured to generate different reference currents as compared to each other and to the reference current Iref1. In some embodiments, the reference currents Iref1 . . . IrefN generated by the reference current sources 234_1 . . . 234_N of the current comparators 222_1 . . . 222_N are defined by the following relationship: Iref1<Iref2<Iref3<Iref4 . . . <IrefN. In an embodiment in which N=7, the reference currents generated by the reference current sources of the current comparators are defined by the following relationships:

Iref1<ID_{—}1;

ID_{—}1<Iref2<ID_{—}2;

ID_{—}2<Iref3<(ID_{—}1+ID_{—}2);

(ID_{—}1+ID_{—}2)<Iref4<(ID_{—}3);

(ID_{—}3)<Iref5<(ID_{—}3+ID_{—}1);

(ID3+ID_{—}1)<Iref6<(ID_{—}3+ID_{—}2); and

(ID_{—}3+ID_{—}2)<Iref7<(ID_{—}3+ID_{—}2+ID_{—}1).

The output signals out_1 . . . out_N from the current comparators 222_1 . . . 222_N are used to determine which of the user input switch devices D_1 . . . DM, if any, is/are closed, e.g., pressed or activated. The following table shows the values of the output signals for different states of the user input switch devices, i.e., closed or open, for a particular embodiment in which the system 100 includes three user input switch devices (M=3) and seven current comparators (N=7). In the columns for the user input switch devices, “1” indicates that the corresponding user input switch device is pressed or closed and “0” indicates that the corresponding user input switch device is not pressed or open. In the columns for the output signals, “1” indicates that the corresponding output signal is high and “0” indicates that the corresponding output signal is low.

| User Input | | | | | | | | | |
|---|---|---|---|---|---|---|---|---|---|
| Switch Devices | | | Output Signals | | | | | | |
| D_3 | D_2 | D_1 | Out_1 | Out_2 | Out_3 | Out_4 | Out_5 | Out_6 | Out_7 |
| 0 | 0 | 0 | 0 | 0 | 0 | 0 | 0 | 0 | 0 |
| 0 | 0 | 1 | 1 | 0 | 0 | 0 | 0 | 0 | 0 |
| 0 | 1 | 0 | 1 | 1 | 0 | 0 | 0 | 0 | 0 |
| 0 | 1 | 1 | 1 | 1 | 1 | 0 | 0 | 0 | 0 |
| 1 | 0 | 0 | 1 | 1 | 1 | 1 | 0 | 0 | 0 |
| 1 | 0 | 1 | 1 | 1 | 1 | 1 | 1 | 0 | 0 |
| 1 | 1 | 0 | 1 | 1 | 1 | 1 | 1 | 1 | 0 |
| 1 | 1 | 1 | 1 | 1 | 1 | 1 | 1 | 1 | 1 |

The output signals out_1 . . . out_N are transmitted to a host device, such as a personal computer or other computing device, or a processor of an electronic device so that the host device or the processor can initiate operations in response to the current states of the user input switch devices D_1 . . . D_M.

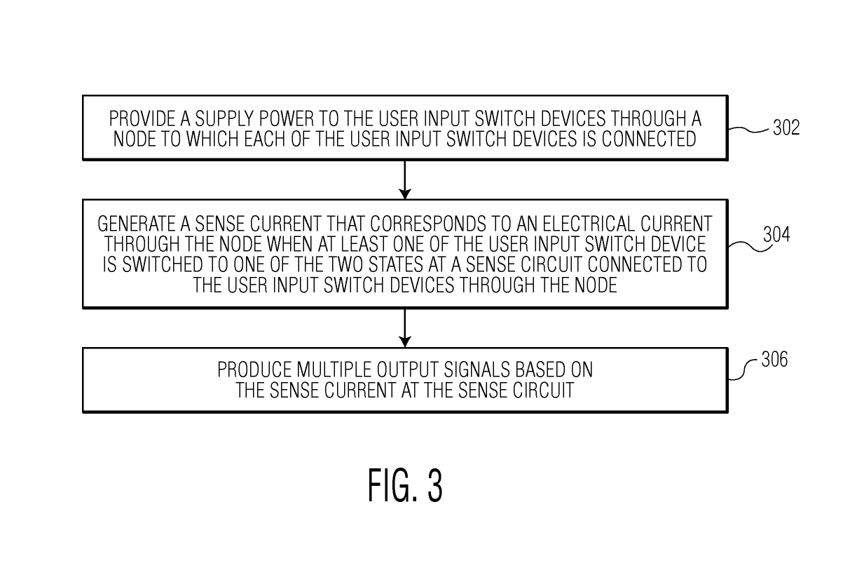

A method for sensing multiple user input switch devices in accordance with an embodiment of the invention is described with reference to a process flow diagram of FIG. 3. At block 302, a supply power is provided to the user input switch devices through a node to which each of the user input switch devices is connected. Each of the user input switch devices is configured to be switched between two states, i.e., open and closed states. At block 304, a sense current is generated that corresponds to an electrical current through the node when at least one of the user input switch device is switched to one of the two states at a sense circuit connected to the user input switch devices through the node. At block 306, multiple output signals are produced based on the sense current at the sense circuit, wherein the multiple output signals indicate current states of the user input switch devices.

Although the operations of the method herein are shown and described in a particular order, the order of the operations of the method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

In addition, although specific embodiments of the invention that have been described or depicted include several components described or depicted herein, other embodiments of the invention may include fewer or more components to implement less or more feature.

Furthermore, although specific embodiments of the invention have been described and depicted, the invention is not to be limited to the specific forms or arrangements of parts so described and depicted. The scope of the invention is to be defined by the claims appended hereto and their equivalents.

What is claimed is:

1. A system comprising:
a plurality of user input switch devices that are each configured to be switched between two states, each of the user input switch devices being connected to a node and connected in parallel to each other; and
a sense circuit electrically connected to the user input switch devices through the node, the sense circuit being configured to generate a sense current that corresponds to an electrical current through the node when at least one of the user input switch device is switched to one of the two states, the sense circuit being configured to produce multiple output signals based on the sense current, wherein the multiple output signals indicate current states of the user input switch devices.

2. The system of claim 1, wherein the sense circuit is part of an integrated circuit, wherein the node is part of a printed circuit board, wherein the user input switch devices are connected to the printed circuit board, and wherein the sense circuit is connected to the printed circuit board through a connection between an integrated circuit package pin of the integrated circuit and the node of the printed circuit board.

3. The system of claim 1, wherein the user input switch devices includes buttons that are each configured to close an electrical current path when pressed and to open the electrical current path when not pressed.

4. The system of claim 1, further comprising a plurality of resistors, each of the user input switch devices being connected in series with one of the resistors between the node and a low voltage rail.

5. The system of claim 4, wherein the resistors are configured to have different resistance values.

6. The system of claim 1, wherein the sense circuit includes a current sensing stage and a current comparing stage, the current sensing stage being configured provide supply power to the user input switch devices and to generate the sense current, the current comparing stage being configured to produce the multiple output signals based on the sense current.

7. The system of claim 6, wherein the current sensing stage includes first and second transistors that connect a power supply rail to the user input switch devices through the node and an operational amplifier connected to the second transistor to control the second transistor, wherein one input of the operational amplifier is connected to receive a predefined voltage and the other input of the operational amplifier being connected to the node to receive the voltage at the node, the current sensing stage further comprising a third transistor to mirror an electrical current through the first transistor to produce the sense current.

8. The system of claim 7, wherein the current comparing stage includes a number of current comparators, each of the current comparators being configured to compare the sense current with a reference current to produce one of the output signals.

9. The system of claim 8, wherein the reference currents used by the current comparators have different values.

10. A system comprising:
a plurality of user input switch devices that are each configured to be switched between two states, each of the user input switch devices being connected in parallel to each other, each of the user input switch devices being connected in series with one of a plurality of resistors between a node and a low voltage rail; and
a sense circuit electrically connected to the user input switch devices through the node, the sense circuit being configured to generate a sense current that corresponds to an electrical current through the node when at least one of the user input switch device is switched to one of the two states, the sense circuit being configured to produce multiple output signals based on the sense current, wherein the multiple output signals indicate current states of the user input switch devices.

11. The system of claim 10, wherein the sense circuit is part of an integrated circuit, wherein the node is part of a printed circuit board, wherein the user input switch devices are connected to the printed circuit board, and wherein the sense circuit is connected to the printed circuit board through a connection between an integrated circuit package pin of the integrated circuit and the node of the printed circuit board.

12. The system of claim 10, wherein the user input switch devices includes buttons that are each configured to close an electrical current path when pressed and to open the electrical current path when not pressed.

13. The system of claim 10, wherein the resistors are configured to have different resistance values.

14. The system of claim 10, wherein the sense circuit includes a current sensing stage and a current comparing stage, the current sensing stage being configured provide supply power to the user input switch devices and to generate the sense current, the current comparing stage being configured to produce the multiple output signals based on the sense current.

15. The system of claim 14, wherein the current sensing stage includes first and second transistors that connect a power supply rail to the user input switch devices through the node and an operational amplifier connected to the second transistor to control the second transistor, wherein one input of the operational amplifier is connected to receive a predefined voltage and the other input of the operational amplifier being connected to the node to receive the voltage at the node, the current sensing stage further comprising a third transistor to mirror an electrical current through the first transistor to produce the sense current.

16. The system of claim 15, wherein the current comparing stage includes a number of current comparators, each of the current comparators being configured to compare the sense current with a reference current to produce one of the output signals.

17. The system of claim 16, wherein the reference currents used by the current comparators have different values.

18. A method for sensing multiple user input switch devices, the method comprising:
providing a supply power to the user input switch devices through a node to which each of the user input switch devices is connected, each of the user input switch devices being configured to be switched between two states;
generating a sense current that corresponds to an electrical current through the node when at least one of the user input switch device is switched to one of the two states at a sense circuit connected to the user input switch devices through the node; and
producing multiple output signals based on the sense current at the sense circuit, wherein the multiple output signals indicate current states of the user input switch devices.

19. The method of claim 18, wherein the providing of the supply power includes providing the supply power from the sense circuit that is part of an integrated circuit through an integrated circuit package pin of the integrated to the node, the node being part of a printed circuit board to which the user input switch devices are connected.

20. The method of claim 18, wherein the producing of the output signals includes comparing the sense current with each reference current from a plurality of reference currents to produce the output signals.
